(19) United States
(12) Patent Application Publication
(10) Pub. No.: US 2018/0350711 A1
(43) Pub. Date: Dec. 6, 2018

(54) INVERSION-TYPE PACKAGE STRUCTURE FOR FLIP CHIP AND FLIP CHIP HAVING THE SAME

(71) Applicant: INSTITUE OF MICROELECTRONICS OF CHINESE ACADEMY OF SCIENCES, Beijing (CN)

(72) Inventors: Zhen MENG, Beijing (CN); Mou LIU, Beijing (CN); Xingcheng ZHANG, Beijing (CN); Xuan TANG, Beijing (CN); Yuepeng YAN, Beijing (CN)

(73) Assignee: INSITUTE OF MICROELECTRONICS OF CHINESE ACADEMY OF SCIENCES, Beijing (CN)

(21) Appl. No.: 15/779,030

(22) PCT Filed: Jan. 6, 2016
(86) PCT No.: PCT/CN2016/070263

§ 371 Date: May 24, 2018

(30) Foreign Application Priority Data
Nov. 25, 2015 (CN) 201510833936.7

(51) Int. Cl. H01L 23/34; H01L 23/498; H01L 23/42; H01L 23/00; H01L 23/13; H01L 23/31; H01L 21/56

(52) U.S. Cl. CPC H01L 23/34; H01L 2924/302; H01L 23/42; H01L 24/05; H01L 24/16; H01L 23/49822; H01L 24/32; H01L 24/73; H01L 23/13; H01L 23/3128; H01L 24/81; H01L 24/92; H01L 24/83; H01L 21/563; H01L 21/565; H01L 2224/0401; H01L 2224/16227; H01L 2224/73204; H01L 2224/32225; H01L 2224/81191; H01L 2224/92225; H01L 2224/83104; H01L 23/49838

(57) ABSTRACT

Embodiments of the present invention disclose an inversion-type package structure for a flip chip and a flip chip having the same, which relate to the technical field of chip packaging, and solve the defect that the existing manners for measuring chip temperature cannot accurately measure the temperature when a die of the flip chip works. The inversion-type package structure for the chip as provided by the present invention comprises a package substrate, a die welded on the package substrate in an inversion manner, a package housing and at least one temperature measuring element, which is characterized in that the at least one temperature measuring element is arranged in a first space below the die in the package substrate, and a residual space except for the space occupied by the at least one temperature measuring element in the first space is filled with an insulating heat conductive substance.

### FIELD OF THE INVENTION

The present invention relates to the technical field of chip packaging, and more particularly, to an inversion-type package structure for a flip chip and a flip chip having the same. The inversion-type package structure for the flip chip and the flip chip having the same are suitable for use in the situation in which the working temperature of a die for the chip is required to be monitored, especially in the technical field of automatic heat dissipation control, in which the temperature of the die for the chip is required to be monitored in real time, so that the working state of the chip per se or that of a heat dissipation apparatus arranged external to the chip can be controlled automatically based on the monitored temperature value.

### BACKGROUND OF THE INVENTION

With the increase in the level of integration for integrated circuits, packaging techniques for chips are also becoming increasingly diverse. Currently, the flip-chip technique, which can shorten the interconnection length within a package and thereby better meet the development requirements of high-degree integration, has been widely used in the field of chip packaging. The flip-chip technique is implemented as follows: pad arrays are directly made onto a transistor active layer of a chip; these pads are used as input terminals and output terminals, and welded on a package substrate in an inversion manner, thereby achieving electric connection between the chip and the substrate.

However, during working, the transistor of the chip would convert a certain proportion of electric energy into heat energy, such that a die of the chip is subjected to temperature increase. Moreover, semiconductor materials for the formation of the die have their own working temperature ranges. As such, when the temperature they experience goes beyond a normal temperature range, the operating state of the transistor deteriorates, and if this temperature is further increased, then the transistor would be burnt up. Therefore, in order to ensure the operational reliability of the chip, its temperature is required to be monitored in real time, such that the heat dissipation apparatus arranged external to the chip can be controlled in real time to accelerate heat dissipation based on the monitored temperature, thereby ensuring the normal operation of the chip. Traditionally, the chip temperature is generally measured outside of the package (as shown in FIG. 1). For example, a temperature measuring element is mounted within the heat dissipation apparatus adhered to a package housing, directly attached on the surface of the package housing or mounted on a loaded circuit board of the flip chip.

In the implementation process of the present invention, the inventor has discovered that there are at least the following technical problems in the prior art:

heat generated from the chip is mainly attributable to the transistor active layer of the die in the chip, and as both the basal insulation layer and the package housing of the die have certain heat resistances, the external temperature of the chip is lower than the actual temperature of the transistor active layer of the die within the chip; as such, the manner of mounting the temperature measuring element within the heat dissipation apparatus adhered to the package housing or directly attaching it on the surface of the package housing cannot accurately measure the actual temperature of the flip-chip die; moreover, the manner of mounting the temperature measuring element on the loaded circuit board of the chip can only measure the temperature of air around the chip, which leads to large measurement errors.

In conclusion, the prior manners for measuring chip temperature cannot accurately measure the temperature when a die of the flip chip works.

### SUMMARY OF THE INVENTION

The present invention provides an inversion-type package structure for a flip chip and a flip chip having the same. In the present invention, the mounting position of a temperature measuring element is reasonably arranged, thereby accurately measuring the operating temperature when a die of the flip chip works.

In one aspect, the present invention provides an inversion-type package structure for a flip chip, which comprises a package substrate, a die welded on the package substrate in an inversion manner, a package housing and at least one temperature measuring element. The at least one temperature measuring element is arranged in a first space below the die in the package substrate, and the residual space except for the space occupied by the at least one temperature measuring element in the first space is filled with an insulating heat conductive substance.

In another aspect, the present invention provides a flip chip comprising the foregoing inversion-type package structure for flip chip.

The present invention provides an inversion-type package structure for flip chip and a flip chip having the same, wherein the inversion-type package structure for flip chip comprises a package substrate, a die welded on the package substrate in an inversion manner, a package housing and at least one temperature measuring element. The at least one temperature measuring element is arranged in a first space below the die in the package substrate, and the residual space except for the space occupied by the at least one temperature measuring element in the first space is filled with an insulating heat conductive substance. As compared with the prior art, the temperature measuring chip in the present invention is mounted in a concave space below the die in the package substrate, such that there is only one insulating heat conductive layer between the temperature measuring device and the die. Accordingly, this mounting manner avoids not only the influences exerted by the heat resistances of the basal insulation layer and the plastic package housing, but also the big error that occurs when only the temperature of air around the flip chip is measured and taken as the actual error thereof. Therefore, the temperature measuring structure designed herein for the flip chip is capable of measuring, in a more accurate manner, the actual temperature produced when the flip-chip die works.

### BRIEF DESCRIPTION OF THE DRAWINGS

In order to illustrate the embodiments of the present invention or the technical solution in the prior art in a clearer manner, the accompanying drawings required to be used in the description of the embodiments or the prior art will be introduced below briefly. Apparently, the accompanying drawings in the following description are merely some embodiments of the present invention, and for those of ordinary skill in the art, other accompanying drawings can be obtained from these accompanying drawings without the exercise of inventive faculty.

FIG. 1 is a structural schematic diagram of a mounting manner for a temperature measuring element of a flip chip in the prior art;

FIG. 2 is a schematic diagram of an embodiment of an inversion-type package structure for a flip chip of the present invention;

FIG. 3 is a structural schematic diagram of another embodiment of the inversion-type package structure for the flip chip of the present invention;

FIG. 4 is a structural schematic diagram of a circuit area and a bonding pad area of a transistor active layer in the above embodiment;

FIGS. 5-9 illustrate a process for making the inversion-type package structure for the flip chip of the present invention.

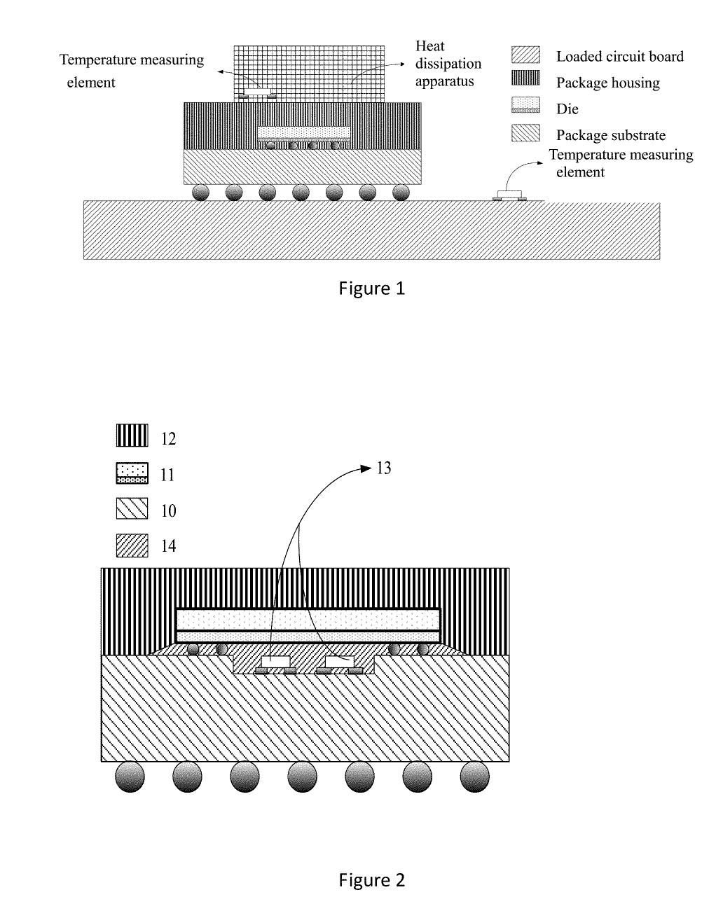

### DETAILED DESCRIPTION OF THE PREFERRED EMBODIMENTS

The technical solutions set forth in the embodiments of the present invention will be described below clearly and thoroughly in conjunction with the accompanying drawings in the embodiments of the present invention. Obviously, the described embodiments only constitute some of the embodiments of the present invention, instead of all the embodiments thereof. Based on the embodiments in the present invention, all other embodiments that are obtained by those of ordinary skill in the art without the exercise of inventive faculty are covered by the scope of protection of the present invention.

As shown in FIG. 2, an embodiment of the present invention provides an inversion-type package structure for a flip chip. The inversion-type package structure for the flip chip comprises a package substrate 10, a die 11 welded on the package substrate 10 in an inversion manner, a package housing 12 and at least one temperature measuring element 13, wherein the at least one temperature measuring element 13 is arranged in a first space 14 below the die 11 in the package substrate 10, and the residual space except for the space occupied by the at least one temperature measuring element 13 in the first space 14 is filled with an insulating heat conductive substance.

The inversion-type package structure for the flip chip as provided by the present invention comprises a die welded on a package substrate in an inversion manner, the package substrate, a package housing and at least one temperature measuring element, wherein the at least one temperature measuring element is arranged in a first space below the die in the package substrate, and the residual space except for the space occupied by the at least one temperature measuring element in the first space is filled with an insulating heat conductive substance. As compared with the prior art, the temperature measuring chip in the present invention is mounted in a concave space below the die in the package substrate, such that there is only one insulating heat conductive layer between the temperature measuring device and the die. Accordingly, this mounting manner avoids not only the influences exerted by the heat resistances of the basal insulation layer and the plastic package housing, but also the big error that occurs when only the temperature of air around the flip chip is measured and taken as the actual error thereof. Therefore, the temperature measuring structure designed herein for the flip chip is capable of measuring, in a more accurate manner, the actual temperature produced when the flip-chip die works.

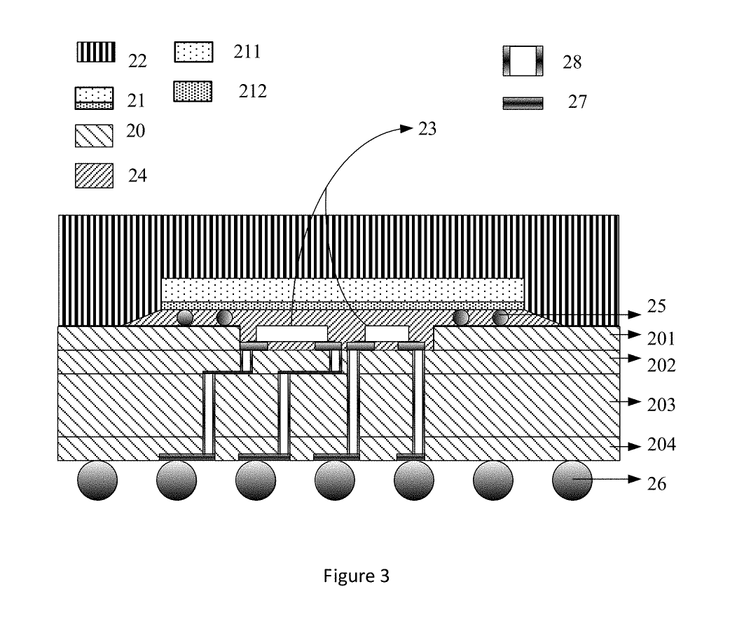

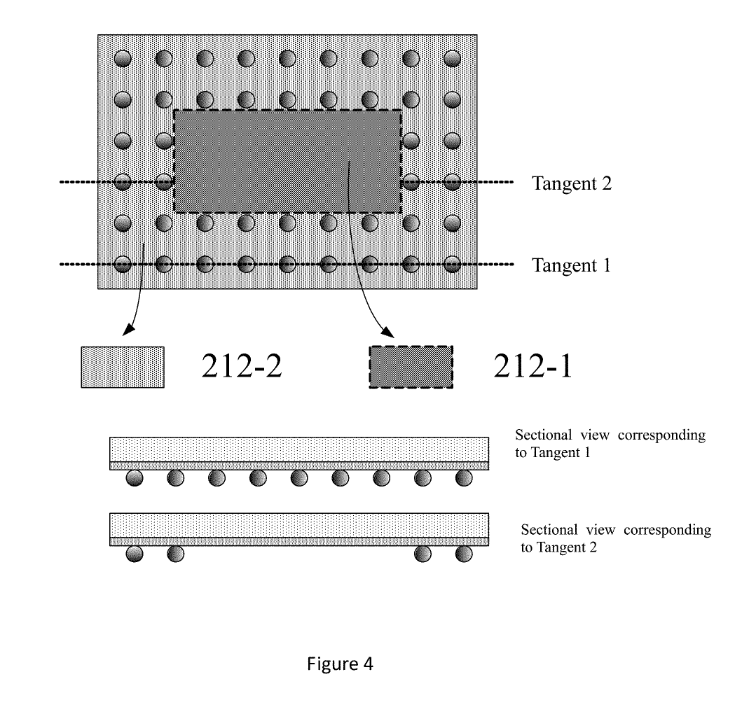

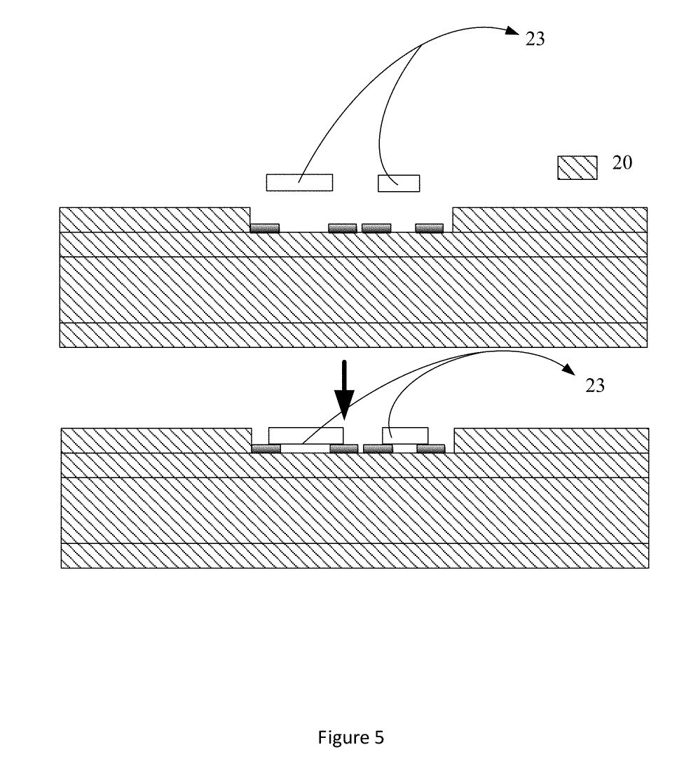

As shown in FIG. 3, the present invention provides an inversion-type package structure for a flip chip. The inversion-type package structure for the flip chip comprises a package substrate 10, a die 21 welded on the package substrate 20 in an inversion manner, a package housing 22 and at least one temperature measuring element 23, wherein the die 21 comprises a basal insulation layer 211 and a transistor active layer 212, and the transistor active layer 212 comprises a circuit area 212-1 and a bonding pad area 212-2 (as shown in FIG. 4); the package substrate 20 is formed by vertically laminating a plurality of insulating dielectric layers, and as an example, four insulating dielectric layers are adopted for illustration; as such, the package substrate 20 is formed by four insulating dielectric layers, which are sequentially a first insulating dielectric layer 201, a second insulating dielectric layer 202, a third insulating dielectric layer 203 and a fourth insulating dielectric layer 204 that are arranged in a manner gradually remote from the die 21; the at least one temperature measuring element 23 is arranged in the first space 24 below the circuit area 212-2 of the transistor active layer 212 in the package substrate 20, the first space 24 is located within the first insulating dielectric layer 201 closest to the die 21, and the residual space except for the space occupied by the at least one temperature measuring element 23 in the first space 24 is filled with an insulating heat conductive glue so as to prevent the occurrence of short circuits between the flip-chip die and the temperature measuring chip, wherein the insulating heat conductive glue can be replaced with other insulating heat conductive substances.

Preferably, after the at least one temperature measuring element 23 is placed in the first space 24, the residual space is filled with the insulating heat conductive glue; thereafter, the process of heat curing is performed to cure the insulating heat conductive glue.

The bonding pad area 212-1 of the transistor active layer 212 is interconnected with the package substrate 20 via solder balls 25. Specifically, the bonding pad area 212-1 of the transistor active layer 212 is interconnected with the first insulating layer 201 via the solder balls 25 so as to achieve the interconnection between the die 21 and the package substrate 20.

In addition, in the inversion-type package structure for flip chip as presented in the embodiment of the present invention, each of the insulating dielectric layers may be provided with conductor interconnecting lines 27 on both sides, and may also be internally provided with a conductor through-hole 28, thereby forming an interconnection structure for connecting the at least one temperature measuring element 23 with external pins 26 of the flip chip. As such, with the external pins 26, each of the above temperature measuring elements 23 can be driven, and monitored temperature values can be read therefrom.

Here, each of the above temperature measuring chips 23 has a thickness less than a thickness of the first insulating dielectric layer 201, and the above various temperature measuring chips 23 are dies or packaged chips.

As compared with the prior art, in the inversion-type package structure for flip chip as provided by the present invention, the temperature measuring chips are mounted in a concave space below the die in the package substrate, such that there is only one insulating heat conductive layer between the temperature measuring device and the die. Accordingly, this mounting manner avoids not only the influences exerted by the heat resistances of the basal insulation layer and the plastic package housing, but also the big error that occurs when only the temperature of air around the flip chip is measured and taken as the actual error thereof. Therefore, the temperature measuring structure designed herein for the flip chip is capable of measuring, in a more accurate manner, the actual temperature produced when the flip-chip die works.

As shown in FIGS. 5-9, illustrated is the process for making the inversion-type package structure for flip chip as presented in the above embodiment, and specifically, the making process comprises the following steps:

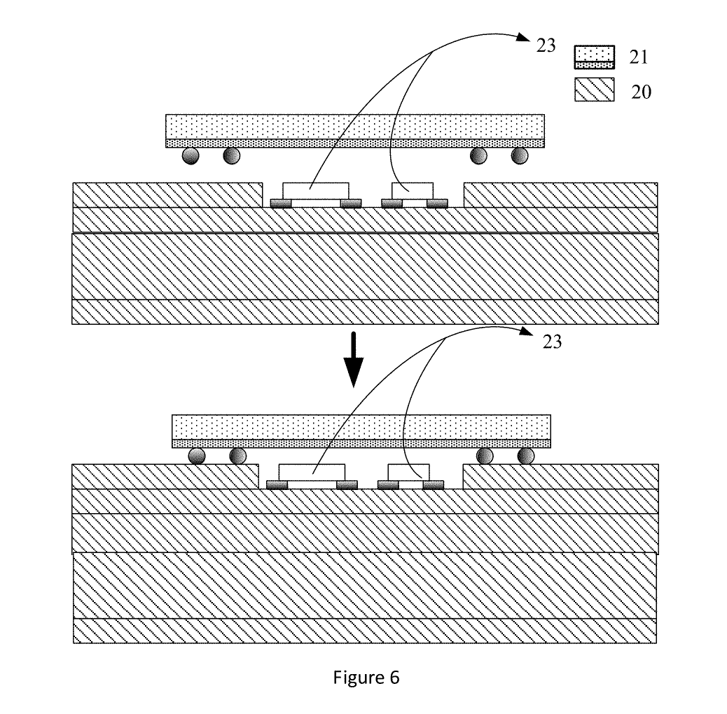

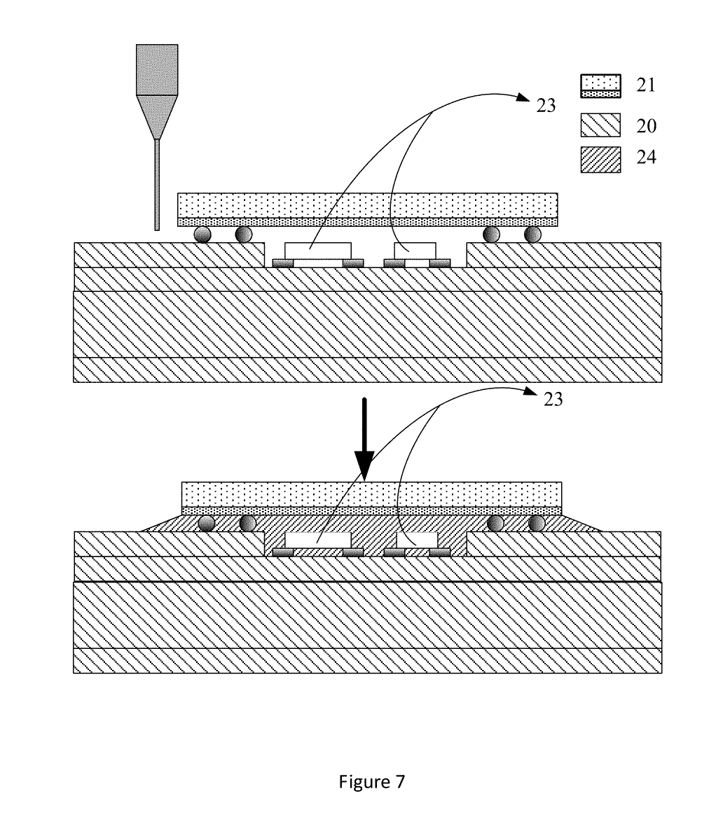

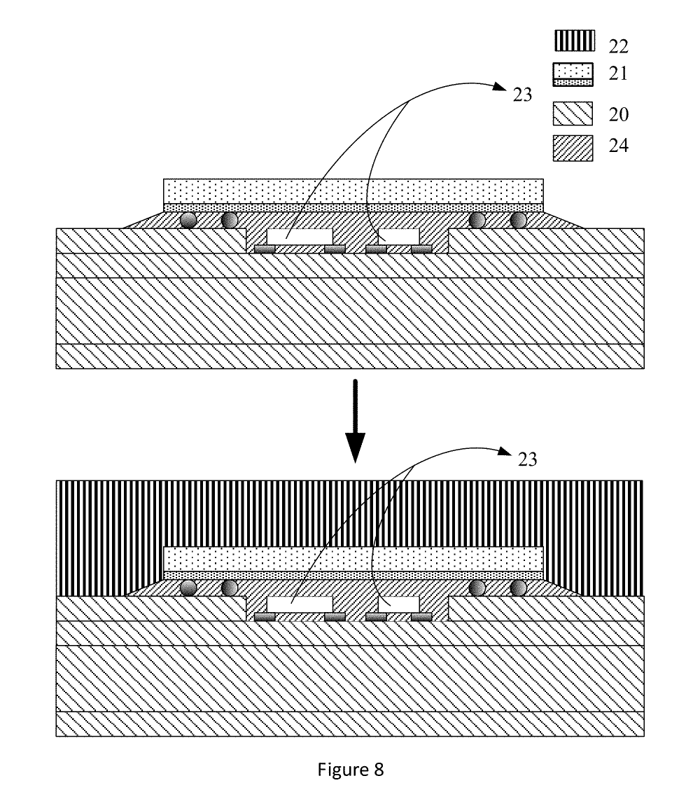

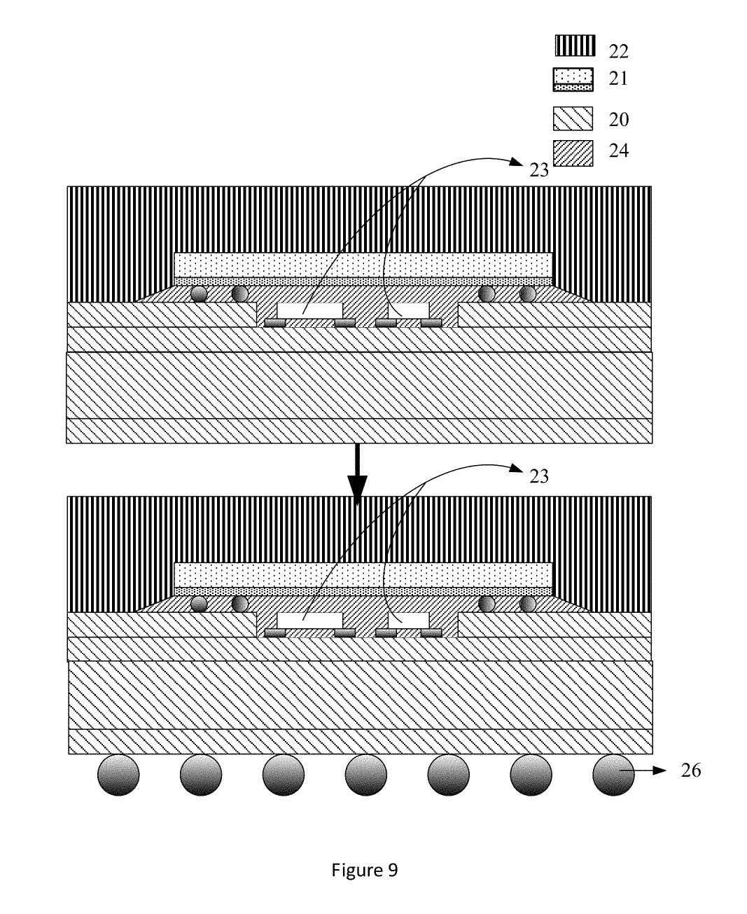

S1 of arranging the at least one temperature measuring element 23 in the package substrate 20 (as shown in FIG. 5);
S2 of welding the die 21 on the package substrate in an inversion manner, thereby forming a first space 24 for receiving the at least one temperature measuring element 23 (as shown in FIG. 6);
S3 of filling a residual space except for the space occupied by the at least one temperature measuring element 23 in the first space 24 with an insulating heat conductive glue, and the insulating heat conductive glue is subjected to the process of heat curing after injection into the residual space (as shown in FIG. 7);
S4 of making the package housing 22 on an upper portion of the package substrate 20 (as shown in FIG. 8);
S5 of making the external pins 26 on a lower portion of the package substrate 20 (as shown in FIG. 9).

In addition, the present invention further provides a flip chip comprising the above inversion-type package structure for flip chip.

What have been described above are merely specific implementations of the present invention, but the scope of protection of the present invention is not limited thereto. For technicians familiar with the art, all the variations or substitutions that can be readily made without departing from the technical scope disclosed by the present invention shall be covered by the scope of protection of the present invention. Therefore, the scope of protection of the present invention shall be subject to that of the claims.

1. An inversion-type package structure for a flip chip, comprising a package substrate, a die welded on the package substrate in an inversion manner, a package housing and at least one temperature measuring element, characterized in that the at least one temperature measuring element is arranged in a first space below the die in the package substrate, and a residual space except for the space occupied by the at least one temperature measuring element in the first space is filled with an insulating heat conductive substance.

2. The inversion-type package structure for the flip chip according to claim 1, characterized by further comprising an interconnection structure for connecting the at least one temperature measuring element with an external pin of the flip chip.

3. The inversion-type package structure for the flip chip according to claim 1, characterized in that the die comprises a basal insulation layer and a transistor active layer, wherein the transistor active layer comprises a circuit area and a bonding pad area, the at least one temperature measuring element is arranged in a first space below the circuit area of the transistor active layer in the package substrate, and the bonding pad area of the transistor active layer is interconnected with the package substrate via a solder ball so as to achieve the interconnection between the die and the package substrate.

4. The inversion-type package structure for the flip chip according to claim 3, characterized in that the package substrate is made by vertically laminating a plurality of insulating dielectric layers, wherein the first space is located within a first insulating dielectric layer closest to the die, and the bonding pad area of the transistor active layer is interconnected with the first insulating layer via the solder ball so as to achieve the interconnection between the die and the package substrate.

5. The inversion-type package structure for the flip chip according to claim 4, characterized in that each of the plurality of insulating dielectric layers is provided with conductor interconnecting lines on both sides, and is also internally provided with a conductor through-hole, thereby forming an interconnection structure for connecting the at least one temperature measuring chip with the external pin of the flip chip.

6. The inversion-type package structure for the flip chip according to any one of claims 1-5, characterized in that the temperature measuring element has a thickness less than a thickness of the first insulating dielectric layer.

7. The inversion-type package structure for the flip chip according to any one of claims 1-5, characterized in that the temperature measuring element is a die or a packaged chip.

8. A flip chip, characterized in that the flip chip has the inversion-type package structure for the flip chip according to any one of claims 1-7.
